(19) United States
(12) Patent Application Publication
(10) Pub. No.: US 2014/0071029 A1
(43) Pub. Date: Mar. 13, 2014

(54) PIXEL AND ORGANIC LIGHT EMITTING DISPLAY DEVICE USING THE SAME

(71) Applicant: SAMSUNG DISPLAY CO., LTD., Yongin-City (KR)

(72) Inventors: Jae-Du Roh, Yongin-City (KR); Yang-Wan Kim, Yongin-City (KR)

(73) Assignee: SAMSUNG DISPLAY CO., LTD., Yongin-City (KR)

(21) Appl. No.: 13/737,166

(22) Filed: Jan. 9, 2013

(30) Foreign Application Priority Data
Sep. 10, 2012 (KR) 10-2012-0100020

(51) Int. Cl. G09G 3/34; H01L 27/32

(52) U.S. Cl. CPC G09G 3/34; H01L 27/3225
USPC 345/82; 257/40

(57) ABSTRACT

There are provided a pixel and an organic light emitting display device using the same capable of improving image quality. A pixel includes an organic light emitting diode, a first transistor, a second transistor and a second capacitor. The first transistor controls the amount of current supplied from a first power to the organic light emitting diode coupled to a second electrode of the first transistor, corresponding to a voltage applied to a second node. The second transistor is coupled between the second electrode of the first transistor and the second node so as to be turned on when a scan signal is supplied to a scan line. The second capacitor is coupled between the second electrode of the first transistor and a control line.

### CLAIM OF PRIORITY

This application makes reference to, incorporates the same herein, and claims all benefits accruing under 35 U.S.C. §119 from an application earlier filed in the Korean Intellectual Property Office on Sep. 10, 2012 and there duly assigned Serial No. 10-2012-0100020.

### BACKGROUND OF THE INVENTION

1. Field of Invention

Embodiments of the present invention relate to a pixel and an organic light emitting display device using the same, and more particularly, to a pixel and an organic light emitting display device using the same capable of improving image quality.

2. Description of the Related Art

Recently, there have been developed various types of flat panel display devices capable of reducing the weight and volume of cathode ray tubes, which are disadvantages. The flat panel display devices include liquid crystal displays, field emission displays, plasma display panels, organic light emitting display devices, and the like.

Among these flat panel display devices, the organic light emitting display devices display images using organic light emitting diodes that emit light through recombination of electrons and holes. The organic light emitting display devices have a fast response speed and are driven with low power consumption.

An organic light emitting display device has a plurality of pixels arranged in a matrix form at intersection portions of a plurality of data lines, a plurality of scan lines and a plurality of power lines. Each of the pixels generally includes an organic light emitting diode, two or more transistors including a driving transistor, and one or more capacitors.

The organic light emitting display device generally has low power consumption. However, in the organic light emitting display device, the amount of current that flows in an organic light emitting diode is changed depending on the variation in the threshold voltage of the driving transistor included in each pixel, and therefore, images with unequal luminance are displayed. That is, characteristics of the driving transistor are changed depending on the fabrication factor of the driving transistor included in each pixel. Practically, it is unlikely in the current fabrication process to fabricate the organic light emitting display device so that all transistors of the organic light emitting display device have the same characteristics. Accordingly, the variation in the threshold voltage of the driving transistor occurs.

To solve such a problem, there has been proposed a method of adding a compensation circuit including a plurality of transistors and capacitors to each pixel. The compensation circuit compensates for a variation in threshold voltage of a driving transistor by allowing the driving transistor to be diode-coupled during a period of supplying a scan signal. Here, a gate electrode of the diode-coupled driving transistor is initialized by an initialization power set to have a low voltage (e.g., a negative voltage) and then receives a data signal supplied.

However, in a case where the gate electrode of the driving transistor is initialized to a low voltage, the compensation of the threshold voltage is not properly made during the period of supplying the scan signal. Specifically, the voltage of the gate electrode of the driving transistor should be increased from the voltage of the initialization power to a voltage corresponding to the data signal and the threshold voltage of the driving transistor. However, since the voltage of the gate electrode of the driving transistor is set to a low negative voltage, the compensation of the threshold voltage is not properly made in a high-resolution panel having a reduced period of supplying a scan signal and/or a panel driven at a high driving frequency.

Further, in a case where the driving transistor is initialized using the initialization power, leakage current is generated from the gate electrode of the driving transistor to the initialization power, and accordingly, an image with a desired luminance is not displayed. Furthermore, since six transistors and two or more capacitors are usually included in a related art compensation circuit, the circuit is complicated, and accordingly, the reliability of the circuit is lowered.

### SUMMARY OF THE INVENTION

Embodiments provide a pixel and an organic light emitting display device using the same capable of improving image quality.

According to an embodiment of the present invention, there is provided a pixel including: an organic light emitting diode; a first transistor that controls the amount of current supplied from a first power to the organic light emitting diode coupled to a second electrode of the first transistor, corresponding to a voltage applied to a second node; a second transistor coupled between the second electrode of the first transistor and the second node so as to be turned on when a scan signal is supplied to a scan line; and a second capacitor coupled between the second electrode of the first transistor and a control line.

A time interval when a control signal supplied to the control line may overlap with a time interval when the scan signal supplied to the scan line during a partial period. The control signal supplied to the control line may be supplied after the scan signal is supplied to the scan line, and the supply of the control signal supplied to the control line may be stopped after the supply of the scan signal to the scan line is stopped. The voltage of the control line may be dropped when the control signal is supplied to the control line, and the voltage of the control line may be raised when the supply of the control signal to the control line is stopped. The pixel may further include a third transistor coupled between a first electrode of the first transistor and a data line so as to be turned on when the scan signal is supplied to the scan line; a fourth transistor coupled between the first electrode of the first transistor and a first power so as to be turned off when an emission control signal is supplied to an emission control line; and a fifth transistor coupled between the second electrode of the first transistor and the organic light emitting diode so as to be turned off when the emission control signal is supplied to the emission control line.

According to an aspect of the present invention, there is provided an organic light emitting display device, including: a scan driver that drives scan lines and emission control lines; a control driver that drives control lines; a data driver that drives data lines; and pixels positioned at intersection portions of the scan lines and the data lines, wherein each pixel positioned on an i-th (i is a natural number) horizontal line includes an organic light emitting diode; a first transistor that controls the amount of current supplied from a first power to the organic light emitting diode coupled to a second electrode of the first transistor, corresponding to a voltage applied to a second node; a second transistor coupled between the second electrode of the first transistor and the second node so as to be turned on when a scan signal is supplied to an i-th scan line; and a second capacitor coupled between the second electrode of the first transistor and an i-th control line.

The time interval when the scan signal supplied to the i-th scan line may overlap with a time interval when a control signal supplied to the i-th control line during a partial period. The control signal supplied to the i-th control line may be supplied after the scan signal is supplied to the i-th scan line, and the supply of the control signal supplied to the i-th control line may be stopped after the supply of the scan signal to the i-th scan line is stopped. When the control signal is supplied to the i-th control line, the voltage of the i-th control line may be dropped from a fourth voltage to a third voltage lower than the fourth voltage. The fourth and third voltages may be set so that the voltage of the second node is dropped to a voltage lower than that of a data signal supplied to a data line.

Each pixel positioned on the i-th horizontal line may further include a third transistor coupled between a first electrode of the first transistor and the data line so as to be turned on when the scan signal is supplied to the i-th scan line; a fourth transistor coupled between the first electrode of the first transistor and a first power so as to be turned off when an emission control signal is supplied to an i-th emission control line; and a fifth transistor coupled between the second electrode of the first transistor and the organic light emitting diode so as to be turned off when the emission control signal is supplied to the i-th emission control line. The time interval when the emission control signal supplied to the i-th emission control line may overlap with the time interval when the scan signal supplied to the i-th scan line. The time interval when the emission control signal supplied to the i-th emission control line may overlap with the time interval when the control signal supplied to the i-th control line. The time interval when the emission control signal supplied to the i-th emission control line may overlap with the time interval when the control signal supplied to the i-th control line during a partial period. The supply of the control signal to the i-th control line may be stopped after the supply of the emission control signal to the i-th emission control line is stopped.

In the pixel and the organic light emitting display device according to the present invention, a diode-coupled driving transistor is turned on at the moment when the voltage of a gate electrode of the driving transistor is dropped to a voltage lower than that of a data signal. Thus, the voltage of the gate electrode of the driving transistor is not excessively dropped, and accordingly, the threshold voltage of the driving transistor can be stably compensated. Further, in the present invention, the gate electrode of the driving transistor is not directly coupled to a low power (e.g., an initialization power), and accordingly, leakage current can be minimized. Furthermore, in the present invention, it is possible to compensate for the threshold voltage of the driving transistor using a relatively simple circuit.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a block diagram illustrating an organic light emitting display device according to an embodiment of the present invention;

FIG. 2 is a circuit diagram illustrating a pixel according to an embodiment of the present invention;

FIG. 3 is a waveform diagram illustrating driving waveforms of a pixel according to a first embodiment of the present invention; and

FIG. 4 is a waveform diagram illustrating driving waveforms of a pixel according to a second embodiment of the present invention.

### DETAILED DESCRIPTION OF THE INVENTION

Hereinafter, certain exemplary embodiments according to the present invention will be described with reference to the accompanying drawings. Here, when a first element is described as being coupled to a second element, the first element may be not only directly coupled to the second element but may also be indirectly coupled to the second element via a third element. Further, some of the elements that are not essential to the complete understanding of the invention are omitted for clarity. Also, like reference numerals refer to like elements throughout.

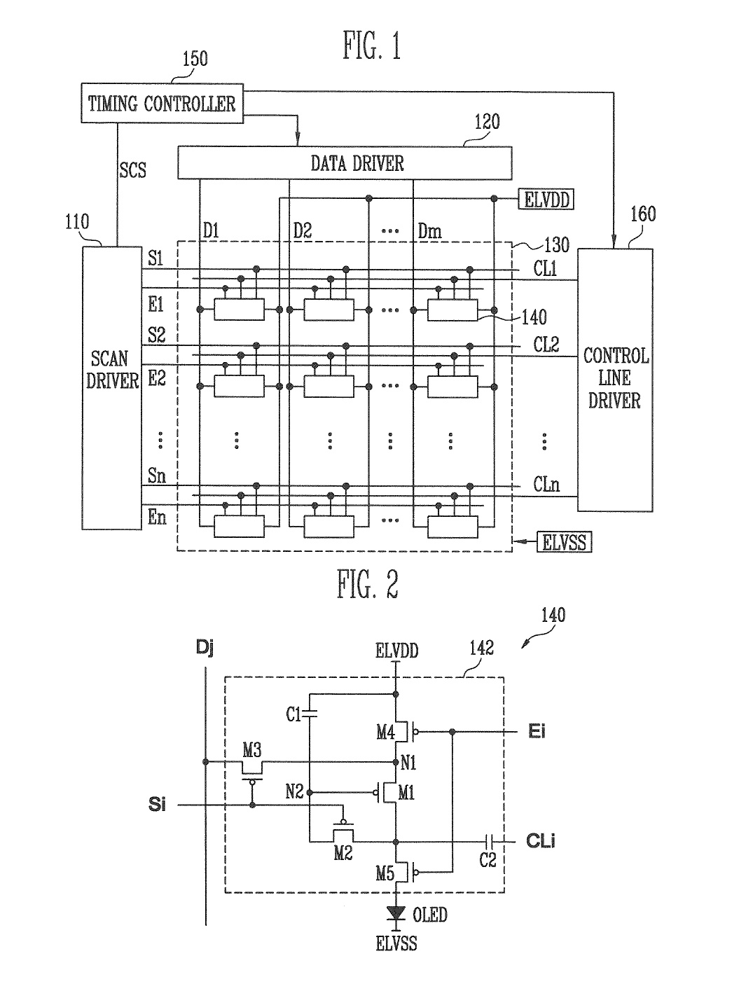

FIG. 1 is a block diagram illustrating an organic light emitting display device according to an embodiment of the present invention.

Referring to FIG. 1, the organic light emitting display device according to this embodiment includes a pixel unit 130 having pixels 140 positioned at intersection portions of scan lines S1 to Sn and data lines D1 to Dm, a scan driver 110 for driving the scan lines S1 to Sn and emission control lines E1 to En, a data driver 120 for driving the data lines D1 to Dm, a control driver 160 for driving control lines CL1 to CLn, and a timing controller 150 for controlling the scan driver 110, the data driver 120 and the control driver 160.

The timing controller 150 controls the scan driver 110, the data driver 120 and the control driver 160, corresponding to synchronization signals supplied from the outside thereof. The timing controller 150 rearranges data supplied from the outside thereof and provides the rearranged data to the data driver 120.

The scan driver 110 generates a scan signal and an emission control signal under the control of the timing controller 150. The scan signal generated in the scan driver 110 is supplied to the scan lines S1 to Sn. For example, the scan driver 110 may progressively supply the scan signal to the first to n-th scan lines S1 to Sn. The emission control signal generated in the scan driver 110 is supplied to the emission control lines E1 to En. For example, the scan driver 110 may progressively supply the emission control signal to the first to n-th emission control lines E1 to En.

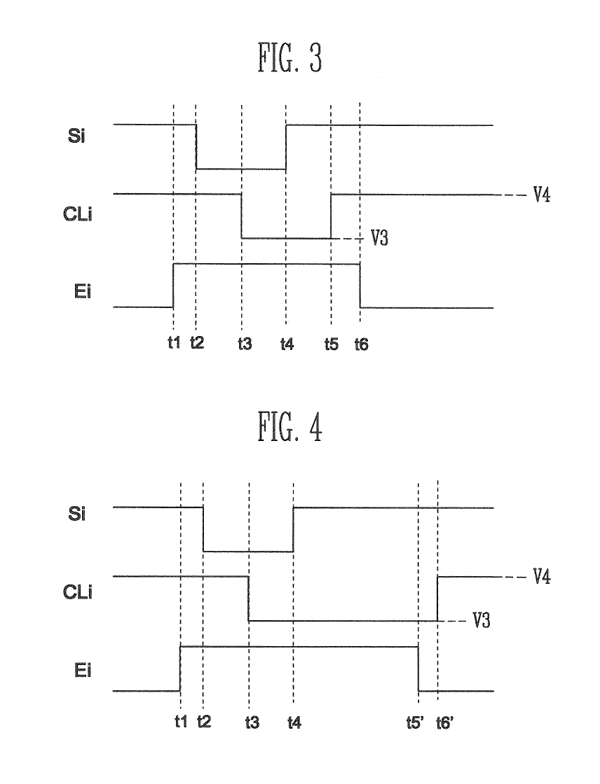

The control driver 160 supplies a control signal to the control lines CL1 to CLn under the control of the timing controller 150. For example, the control driver 160 may progressively supply the control signal to the first to n-th control lines CL1 to CLn. Here, a time interval when the control signal supplied to an i-th (i is a natural number and 1≦i≦n) control line CLi overlaps with a time interval when the scan signal supplied to an i-th scan line Si during a partial period. For example, as shown in FIGS. 3 and 4, the control signal supplied to the i-th control line CLi is supplied after the scan signal is supplied to the i-th scan line Si, and is supplied so as to overlap with a time interval when the scan signal supplied to the i-th scan line Si.

A time interval when the emission control signal supplied to the i-th emission control line Ei overlaps with a time interval when the scan line supplied to the i-th scan line Si, and is supplied so as to overlap with a time interval when the control signal supplied to the i-th control line CLi during at least a partial period. The emission control signal will be described in conjunction with FIGS. 3 and 4.

The data driver 120 supplies a data signal to the data lines D1 to Dm so as to be synchronized with the scan signal under the control of the timing controller 150.

The pixel unit 130 receives voltages of a first power ELVDD and a second power ELVSS, supplied from an external power source thereof, and supplies the received voltages to the pixels 140. Each pixel 140 charges a voltage corresponding to the data signal while being initialized corresponding to the control signal supplied from a control line (any one of CL1 to CLn) coupled to the pixel 140 itself. Each pixel 140 that has charges the voltage corresponding to the data signal emits light with a predetermined luminance while controlling the amount of current supplied to the second power ELVSS via an organic light emitting diode (not shown).

FIG. 2 is a circuit diagram illustrating a pixel according to an embodiment of the present invention. For convenience of illustration, a pixel coupled to the i-th scan line Si and a j-th (j is a natural number and 1≦j≦m) data line Dj is shown in FIG. 2.

Referring to FIG. 2, the pixel 140 according to this embodiment includes an organic light emitting diode OLED and a pixel circuit 142 coupled to a data line Dj, a scan line Si, an emission control line Ei and a control line CLi so as to control the amount of current supplied to the organic light emitting diode OLED.

An anode electrode of the organic light emitting diode LED is coupled to the pixel circuit 142, and a cathode electrode of the organic light emitting diode LED is coupled to a second power ELVSS. Here, the voltage of the second power ELVSS is set lower than that of a first power ELVDD. The organic light emitting diode OLED emits light with a predetermined luminance corresponding to the amount of current supplied from the pixel circuit 142.

The pixel circuit 142 receives a data signal supplied from the data line Dj when a scan signal is supplied to the scan line Si. The pixel circuit 142 charges a voltage corresponding to the data signal in a storage capacitor Cst when a control signal is supplied to the control line CLi. To this end, the pixel circuit 142 includes first through fifth transistors M1 through M5, a first capacitor C1 and a second capacitor C2.

A first electrode of the first transistor M1 is coupled to a first node N1, and a second electrode of the first transistor M1 is coupled to a first electrode of the fifth transistor M5. A gate electrode of the first transistor M1 is coupled to a second node N2. The first transistor M1 supplies, to the organic light emitting diode OLED, current corresponding to a voltage applied to the second node N2, i.e., the voltage charged in a first capacitor C1 which will be discussed later.

A first electrode of the second transistor M2 is coupled to the second electrode of the first transistor M1, and a second electrode of the second transistor M2 is coupled to the second node N2. A gate electrode of the second transistor M2 is coupled to the i-th scan line Si. The second transistor M2 is turned on when the scan signal is supplied to the i-th scan line Si so as to allow the first transistor M1 to be diode-coupled.

A first electrode of the third transistor M3 is coupled to the data line Dj, and a second electrode of the third transistor M3 is coupled to the first node N1. A gate electrode of the third transistor M3 is coupled to the i-th scan line Si. The third transistor M3 is turned on when the scan signal is supplied to the i-th scan line Si so as to allow the data line Dj and the first node N1 to be electrically coupled to each other.

A first electrode of the fourth transistor M4 is coupled to the first power ELVDD, and a second electrode of the fourth transistor M4 is coupled to the first node N1. A gate electrode of the fourth transistor M4 is coupled to the emission control line Ei. The fourth transistor M4 is turned off when an emission control signal is supplied to the emission control line Ei, and is turned on when the emission control signal is not supplied to the emission control line Ei.

The first electrode of the fifth transistor M5 is coupled to the second electrode of the first transistor M1, and a second electrode of the fifth transistor M5 is the anode electrode of the organic light emitting diode OLED. A gate electrode of the fifth transistor M5 is coupled to the emission control line Ei. The fifth transistor M5 is turned off when the emission control signal is supplied to the emission control line Ei, and is turned on when the emission control signal is not supplied to the emission control line Ei.

The first capacitor C1 is coupled between the first power ELVDD and the second node N2. The first capacitor C1 stores a voltage applied to the second node N2, i.e., a voltage corresponding to the data signal and the threshold voltage of the first transistor M1

The second capacitor C2 is coupled between the i-th control line CLi and the second electrode of the first transistor M1. The second capacitor C2 controls the voltage of the second node N2, corresponding to a variation in voltage of the i-th control line CLi. Practically, the second capacitor C2 controls the voltage of the second node N2 so that the diode-coupled first transistor M1 can be turned on.

FIG. 3 is a waveform diagram illustrating driving waveforms according to a first embodiment of the present invention.

Referring to FIG. 3, at time t1, a high-level emission control signal is first supplied to the emission control line Ei so that the fourth and fifth transistors M4 and M5 are turned off. If the fourth transistor M4 is turned off, the first power ELVDD and the first node N1 are electrically cut off. If the fifth transistor M5 is turned off, the first transistor M1 and the organic light emitting diode OLED are electrically cut off. Therefore, the organic light emitting diode OLED is set to be in a non-emission state during a period in which the high-level emission control signal is supplied to the emission control line Ei.

Then, at time t2, a low-level scan signal is supplied to the i-th scan line Si so that the third and second transistors M3 and M2 are turned on. If the second transistor M2 is turned on, the first transistor M1 is diode-coupled. If the third transistor M3 is turned on, a data signal from the data line Dj is supplied to the first node N1.

In this case, the first transistor M1 is turned on or turned off, corresponding to a voltage applied to the second node N2. For example, in a case where the data signal supplied during a previous frame period is set to a lower signal than that supplied during a current frame period, i.e., in a case where the voltage of the second node N2 is set lower than that of the first node N1, the first transistor M1 is turned on. In this case, the data signal supplied during the current frame period and the voltage corresponding to the threshold voltage of the first transistor M1 are charged in the first capacitor C1.

In a case where the data signal supplied during the previous frame period is set to a higher voltage than that supplied during the current frame period, i.e., in a case where the voltage of the second node N2 is set higher than that of the first node N1, the first transistor M1 maintains a turn-off state. Then, for convenience of illustration, it is assumed that the first transistor M1 is set to be in a turn-off state during a period in which the data signal is supplied to the first node N1. Practically, when the threshold voltage of the first transistor M1 is considered, the first transistor M1 is mostly set to be in the turn-off state during the period in which the data signal is supplied to the first node N1.

After the data signal is supplied to the first node N1, a control signal is supplied to the control line CLi at time t3. More specifically, at time t3, the voltage of the control line CLi is dropped from a fourth voltage V4 to a third voltage V3. In this case, the voltage of the second node N2 is also dropped by coupling of the second capacitor C2.

The first transistor M1 is turned on when the voltage of the second node N2 is set lower than that of the first node N1. If the first transistor M1 is turned on, the voltage obtained by subtracting the threshold voltage of the first transistor M1 from the voltage of the data signal supplied to the first node N1 is applied to the second node N2. In this case, the voltage applied to the second node N2 is charged in the first capacitor C1.

Meanwhile, in the present invention, the difference between the fourth and third voltages V4 and V3 is set so that the voltage of the second node N2 is dropped to a voltage lower than that of the data signal by the coupling of the second capacitor C2. Then, the voltage of the second node N2 can be stably initialized so that the first transistor M1 can be turned on during the period in which the control signal is supplied to the control line CLi.

After a predetermined voltage is charged in the first capacitor C1, the supply of the low-level scan signal to the n-th scan line is stopped at time t4. If the supply of the low-level scan signal to the i-th scan line Si is stopped, the second and third transistors M2 and M3 are turned off.

Then, at time t5, the supply of the control signal, which has the voltage of V3, to the i-th control line CLi is stopped. If the supply of the control signal to the i-th control line CU is stopped, the voltage of the second electrode of the first transistor M1 rises. In this case, the second transistor M2 is set to be in a turn-off state, and hence the second node N2 maintains the voltage charged during the previous frame period.

Then, at time t6, the supply of the high-level emission control signal to the emission control line E1 is stopped so that the fourth and fifth transistors M4 and M5 are turned on. If the fourth and fifth transistors M4 and M5 are turned on, a current path is formed from the first power ELVDD to the second power ELVSS via the first transistor M1 and the organic light emitting diode OLED. In this case, the first transistor M1 supplies, to the organic light emitting diode OLED, current corresponding to the voltage applied to the second node N2.

In the present invention, the first transistor M1 is turned on at the moment when the voltage of the second node N2 is ideally dropped to a voltage lower than that of the first node N1. That is, in the present invention, the voltage of the second node N2 is not initialized to an excessively low voltage, and accordingly, is raised to a desired voltage within a fast time. Thus, in the present invention, the threshold voltage of the first transistor M1 can be stably compensated.

In the present invention, the second node N2 is not directly coupled to a low power (e.g., an initialization power), and hence leakage current can be minimized. Accordingly, it is possible to display an image with a desired luminance. Further, in the present invention, it is possible to compensate for the threshold voltage of the first transistor M1 using a relatively simple circuit.

FIG. 4 is a waveform diagram illustrating driving waveforms according to a second embodiment of the present invention. In FIG. 4, detailed descriptions of portions identical to those in FIG. 3 will be omitted.

Referring to FIG. 4, in the second embodiment of the present invention, the supply of a control signal, which has a low-level voltage of V3, to the control line CLi is stopped at time t6′ after the supply of a high-level emission control signal to the emission control line Ei is stopped at time t5′.

Specifically, the second electrode of the first transistor M1 is set to be in a floating state during a period in which the high-level emission control signal is supplied to the emission control line Ei. Therefore, in a case where the supply of the control signal (V3) to the control line CU is stopped at time t5 during the period in which the high-level emission control signal is supplied to the emission control line Ei as shown in FIG. 3, the voltage of the second electrode of the first transistor M1 rises.

In a case where the voltage of the second electrode of the first transistor M1 rises, the voltage of the second node N2 may be raised by a parasitic capacitor of the first transistor M1. Here, the rise of the voltage of the second node N2 has a positive effect so that it is possible to compensate for loss of the data signal and to obtain more natural black. However, the parasitic capacitor is a capacitor that is not intended by a designer, and the capacitor for each pixel 140 may be unequally set. In other words, the increment of the voltage of the second node is differently set in each pixel 140, and therefore, an unequal image may be displayed.

Therefore, in the second embodiment of the present invention, the supply of the high-level emission control signal to the emission control line Ei is stopped at time t5′ so that the supply of the control signal (V3) to the control line CLi is stopped during the period in which a predetermined voltage is applied to the second electrode of the first transistor M1. In this case, the predetermined voltage is applied to the second electrode of the first transistor M1, and hence a change in voltage due to the stop of the supply of the control signal does not occur.

PMOS transistors have been described as an example of transistors included in the embodiments of the present invention. However, embodiments of the present invention are not limited thereto. For example, NMOS transistors may additionally or alternatively be used, and consequently in this case, the logically high-level signals described above may be replaced with logically low-level signals and the logically low-level signals described above may be replaced with logically high-level signals.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A pixel comprising:
an organic light emitting diode;
a first transistor having a second electrode coupled to the organic light emitting diode, said first transistor controlling an amount of current supplied from a first power to the organic light, emitting diode in accordance with a voltage applied to a second node;
a second transistor coupled between the second electrode of the first transistor and the second node so as to be turned on when a scan signal is supplied to a scan line; and
a second capacitor coupled between the second electrode of the first transistor and a control line.

2. The pixel according to claim 1, wherein a time interval when a control signal supplied to the control line overlaps with a time interval when the scan signal supplied to the scan line during a partial period.

3. The pixel according to claim 2, wherein the control signal supplied to the control line is supplied after the scan signal is supplied to the scan line, and the supply of the control signal supplied to the control line is stopped after the supply of the scan signal to the scan line is stopped.

4. The pixel according to claim 1, wherein the voltage of the control line is dropped when the control signal is supplied to the control line, and the voltage of the control line is raised when the supply of the control signal to the control line is stopped.

5. The pixel according to claim 1, farther comprising:
a third transistor coupled between a first electrode of the first transistor and a data line so as to be turned on when the scan signal is supplied to the scan line;
a fourth transistor coupled between the first electrode of the first transistor and the first power so as to be turned off when an emission control signal is supplied to an emission control line; and
a fifth transistor coupled between the second electrode of the first transistor and the organic light emitting diode so as to be turned off when the emission control signal is supplied to the emission control line.

6. An organic light emitting display device, comprising:
a scan driver that drives scan lines and emission control lines;
a control driver that drives control lines;
a data driver that drives data lines; and
pixels positioned at intersection portions of the scan lines and the data lines,
each pixel positioned on an i-th (i is a natural number) horizontal line comprising:
an organic light emitting diode;
a first transistor having a second electrode coupled to the organic light emitting diode, said first transistor controlling an amount of current supplied from a first power to the organic light emitting diode in accordance with a voltage applied to a second node;
a second transistor coupled between the second electrode of the first transistor and the second node so as to be turned on when a scan signal is supplied to an i-th scan line; and
a second capacitor coupled between the second electrode of the first transistor and an i-th control line.

7. The organic light emitting display device according to claim 6, wherein a time interval when the scan signal supplied to the i-th scan line overlaps with a time interval when a control signal supplied to the i-th control line during a partial period.

8. The organic light emitting display device according to claim 7, wherein the control signal supplied to the i-th control line is supplied after the scan signal is supplied to the i-th scan line, and the supply of the control signal supplied to the i-th control line is stopped after the supply of the scan signal to the i-th scan line is stopped.

9. The organic light emitting display device according to claim 7, wherein when the control signal is supplied to the i-th control line, the voltage of the i-th control line is dropped from a fourth voltage to a third voltage lower than the fourth voltage.

10. The organic light emitting display device according to claim 9, wherein the fourth and third voltages are set so that the voltage of the second node is dropped to a voltage lower than that of a data signal supplied to a data line.

11. The organic light emitting display device according to claim 7, wherein each pixel positioned on the i-th horizontal line further comprises:
a third transistor coupled between a first electrode of the first transistor and the data line so as to be turned on when the scan signal is supplied to the i-th scan line;
a fourth transistor coupled between the first electrode of the first transistor and the first power so as to be turned off when an emission control signal is supplied to an i-th emission control line; and
a fifth transistor coupled between the second electrode of the first transistor and the organic light emitting diode so as to be turned off when the emission control signal is supplied to the i-th emission control line.

12. The organic light emitting display device according to claim 11, wherein a time interval when the emission control signal supplied to the i-th emission control line overlaps with the time interval when the scan signal supplied to the i-th scan line.

13. The organic light emitting display device according to claim 12, wherein the time interval when the emission control signal supplied to the i-th emission control line overlaps with the time interval when the control signal supplied to the i-th control line.

14. The organic light emitting display device according to claim 12, wherein the time interval when the emission control signal supplied to the i-th emission control line overlaps with the time interval when the control signal supplied to the i-th control line during a partial period.

15. The organic light emitting display device according to claim 14, wherein the supply of the control signal to the i-th control line is stopped after the supply of the emission control signal to the i-h emission control line is stopped.
